(19) United States
(12) Patent Application Publication
(10) Pub. No.: US 2005/0037240 A1
(43) Pub. Date: Feb. 17, 2005

(54) Protective coat and method for manufacturing thereof

(76) Inventors: Daisaku Haoto, Tokyo-to (JP); Kenji Tanaka, Tokyo-to (JP)

Correspondence Address: Richard J. Streit;Ladas & Parry, Suite 1200, 224 South Michigan Avenue, Chicago, IL, 60604, US

(21) Appl. No.: 10/813,538

(22) Filed: Mar. 30, 2004

(30) Foreign Application Priority Data
Mar. 31, 2003 (JP) P2003-093774
Mar. 31, 2003 (JP) P2003-093775
Jul. 15, 2003 (JP) P2003-197126

(51) Int. Cl. B32B 9/00; C23C 14/32

(52) U.S. Cl. 428/698; 428/336; 427/579; 204/192.15

(57) ABSTRACT

A method for producing a protective coat formed on the top surface of a substrate, or on the top surface of a thin film layered body formed on the substrate is disclosed, wherein the protective coat comprises silicon oxynitride in which the atomic ratio of Si/O/N is 100/X/Y (130≦X+Y≦180, 10≦X≦135, 5≦Y≦150), wherein the protective coat is formed by a sputtering method in which silicon nitride is used as a target material, an inert gas is used as a sputtering gas, and N₂ is used as a reactive feed gas. The oxygen component of the obtained protective coat comprising the silicon oxynitride is incorporated into the composition of the protective coat by degradation of moisture that was present in the substrate or the thin film layered body or in the reaction apparatus.

### BACKGROUND OF THE INVENTION

1. Technical Field

The present invention relates to a protective coat formed on the top surface of a substrate, or on the top surface of a thin film layered body formed on the substrate and to a method for manufacturing thereof. More specifically, the present invention relates to a method for production that enables mass production at stable high quality of a protective coat such as, for example, a barrier layer formed on an organic layer in which it is difficult to cure an internal part of the film, such as a UV curable resin, which is a so-called “overcoat layer” usable in organic electroluminescent devices and the like, or a barrier layer of a film having a high moisture content, such as polyethersulfone (PES), polyethylene naphthalate (PEN), acrylic UV curable resins and the like used in packaging materials, display devices and the like.

2. Related Art

Liquid crystal display panels are currently widely used as flat display panels, and in recent years devices that use electroluminescent devices (hereafter, referred to as “EL devices”) that are lightweight and do not require a backlight are drawing attention.

Both organic and inorganic EL devices are being developed. While inorganic EL devices require a comparatively high voltage for driving, organic EL devices have a characteristic whereby a very high level of brightness of from several hundred to several tens of thousand cd/m² can be obtained by a low voltage of about 10 volts. Therefore organic EL devices are becoming prevalent.

However, a problem exists concerning organic EL devices whereby due to adsorption of moisture and organic solvent components, for example, black spots that are referred to as “dark spots” are generated in a light emitting device and the generated dark spots grow to decrease the life span of the organic EL device.

Further, in organic EL devices, a difference in level is generated when forming a colour filter or the like on a substrate. Thus, when forming a transparent electrode and auxiliary wiring thereon, the concern arises that the transparent electrode and auxiliary wiring will be disconnected. An organic layer is therefore provided for planarization, and the structure is constituted to form an ITO electrode or the like on the organic layer. However, due to heat generated upon activation of a display or the like, moisture or organic solvent components in the organic layer volatilize and are released as gas. A problem thus exists that the function of the light-emitting device deteriorates and reliability decreases.

Thus, while resin substrates and resin films are used for displays such as organic EL displays and LCDs and for food packaging, conventionally a barrier layer is formed to block oxygen or moisture from entering an internal part as described above. With respect to resin substrates for use in displays, a barrier layer formed by sputtering or vapor deposition of silicon oxides had been used for reasons associated with transparency and moisture resistance, however this method did not satisfactorily fulfill the required function.

To solve the above problems, US2002093285A1 proposes the use of silicon oxynitride in which the nitride/oxide ratio is 0.13 to 2.88 as a barrier film for organic EL devices.

### SUMMARY OF THE INVENTION

However, in the above US2002093285A1, the barrier properties are discussed in terms of the O/N ratio, and it is an uncertain factor regarding the quality thereof.

Further, a silicon oxynitride film is formed using oxygen as an introduced gas for a SiN target. However, in studies performed by the present inventors in which we designed for industrial mass production and conducted production using actual equipment when using oxygen in this way, variations in quality arose and it was difficult to obtain the desired composition.

Further, when fabricating a barrier film comprising SiON film or the like, there are many cases of using a target with a slow sputter rate, such as SiN. Thus, when using a substrate conveyor-type production apparatus, such as an in-line sputtering apparatus, there are cases where the speed at which substrates are conveyed is very slow.

In such cases, the end of a substrate on a side near a target is, in the initial stage of film formation, liable to receive a large influence from gas emitted from the substrate or the like, and the end of a substrate farther from a target is less subject to the influence of the gas. In addition, this tendency is more noticeable as the size of a substrate increases. Thus, the influence of gas emitted from a substrate is received in the initial stage of film formation (the leading edge part in the direction of movement of a substrate), and because gas emitted from the base is blocked as film formation proceeds, in the latter stage of film formation (the trailing edge part in the direction of movement of a substrate) hardly any influence is received from emitted gas.

As a result, depending on the conveying direction of a substrate, inhomogeneity of composition distribution derived from emitted gas is generated in the resulting barrier film, and in-plane variations arise in barrier properties. This provokes deterioration in the production process caused by in-plane non-uniformities at the time of electrode formation and processing, and also provokes product deterioration due to non-uniform generation of distribution over time in the plane of products such as organic EL devices, thus constituting a problem.

Therefore, an object of the present invention is to provide an improved protective coat that solves the above-described problems in the conventional art and a method for producing the protective coat.

Another object of the present invention is to provide, by an improved process, a method for producing a protective coat that enables stable mass production of high quality protective coats that are superior in terms of barrier properties, visible light transparency and uniformity in film quality.

A further object of the present invention is to provide a protective coat that inhibits the influence of gas emitted from a lower layer such as a substrate, and has a predetermined film thickness and prescribed composition uniformly in the in-plane thereof, and a method for manufacturing thereof.

A still further object of the present invention is to provide a protective coat and a method for manufacturing thereof, wherein the protective coat prevents deterioration of film properties of an electrode and patterning degradation at a time of electrode formation caused by a gas such as oxygen or moisture emitted from a lower layer, and is useful in obtaining a long-lasting organic EL device or the like in which stable EL luminescence properties and the like are maintained uniformly in the in-plane over a long period after formation of a device.

The present invention that solves the above problems is a protective coat formed on the top surface of a substrate, or on the top surface of a thin film layered body formed on the substrate and is characterized by comprising silicon oxynitride in which the atomic ratio of Si/O/N is 100/X/Y (130≦X+Y≦180, 10≦X≦135, 5≦Y≦150).

The present invention further provides a protective coat in which the above thin film layered body includes an organic luminescent layer.

The present invention that solves the above problems further provides a method for producing a protective coat that is formed on a top part of a thin film layered body formed on a top part of a substrate or on a substrate and that comprises silicon oxynitride in which the atomic ratio of Si/O/N is 100/X/Y (130≦X+Y≦180, 10≦X≦135, 5≦Y≦150), wherein the protective coat is formed by a sputtering method in which silicon nitride is used as a target material, an inert gas is used as a sputtering gas, and N₂ is used as a reactive feed gas.

The present invention that solves the above problems further provides a method for producing a protective coat that is formed on a top part of a thin film layered body formed on a top part of a substrate or on a substrate and that comprises silicon oxynitride in which the atomic ratio of Si/O/N is 100/X/Y (130≦X+Y≦180, 10≦X≦135, 5≦Y≦150), wherein the protective coat is formed by an ion plating method using silicon nitride as a material and using N₂ as a reactive feed gas.

The present invention further provides the above method for producing a protective coat, characterized in that an oxygen component of an obtained protective coat comprising silicon oxynitride is incorporated into the composition of the protective coat by degradation of moisture that was present in a substrate or a thin film layered body or in a reaction apparatus.

The present invention also provides the above method for producing a protective coat comprising silicon oxynitride, which is performed using an in-line sputtering apparatus, employing conditions of an applied voltage of 2.50 to 7.00 W/cm² and a distance between a target and a substrate of 12 cm or less.

According to a protective coat of a first aspect of the present invention described above and a method for manufacturing thereof, stable mass production of a protective coat that is of superior quality with respect to barrier properties, visible light transmittance and film uniformity is enabled when forming a protective coat on a top part of a thin film layered body formed on a top part of a substrate or on a substrate and, for example, when the protective coat is applied as a barrier layer in an organic EL device, it is possible to efficiently inhibit deterioration caused by moisture, oxygen and the like of the organic EL device.

The present invention that solves the above problems further provides a protective coat formed on the top surface of a substrate, or on the top surface of a thin film layered body formed on the substrate, wherein the protective coat is characterized by comprising two or more layers having at least a comparatively thin first layer formed on a top part of a thin film layered body formed on a top part of a substrate or on a substrate, and a comparatively thick second layer formed on a top part of the first layer and having a different composition to the first layer.

The present invention further provides the above protective coat, in which the first layer is an oxide film and the second layer is a nitride oxide film or a nitride film, and further, the first layer is a SiOx film and the second layer is a SiONx film or SiNx film.

The present invention also provides the above protective coat, characterized in that the first layer does not grow in an island shape and forms a continuous layer uniformly covering a lower layer, and has a thickness of 1500 A or less.

The present invention further provides a protective coat in which the above thin film layered body includes an organic luminescent layer.

The present invention that solves the above problems further provides a method for producing the above protective coat, characterized in that a protective coat comprising two or more layers of different compositions is formed in a vacuum process using the same raw materials for film formation by controlling a conveying speed, in which a first layer of film is formed while being allowed to react with a component of a gas emitted from a substrate or a thin film layered body formed on a substrate, and subsequently, at a time of formation of a second layer, the obtained first layer is applied as a cap layer to block gas emitted from a substrate or a thin film layered body formed on a substrate.

The present invention also provides a method for producing a protective coat, characterized in that the above first layer is an oxide film and the second layer is a nitride oxide film or a nitride film, and in which an oxygen component of an obtained protective coat is incorporated into the composition of the protective coat by degradation of moisture that was present in a substrate or a thin film layered body or in a reaction apparatus.

According to a protective coat of a second aspect of the present invention described above and a method for manufacturing thereof, a protective coat can be provided that inhibits the influence of a gas emitted from a lower layer such as a substrate and that has a prescribed film thickness and a prescribed composition uniformly in the in-plane thereof. It is thus possible to obtain a protective coat that prevents deterioration of film properties of an electrode and patterning degradation at a time of electrode formation caused by a gas such as oxygen or moisture emitted from a lower layer, and which is useful in obtaining a long-lasting organic EL device or the like in which stable EL luminescence properties and the like are maintained uniformly in the in-plane over a long period after formation of a device.

### BRIEF DESCRIPTION OF THE DRAWINGS

FIG. 1 is a diagram showing evaluation points for a substrate according to an example of the present invention; and

FIG. 2 is a schematic diagram showing one example of a protective coat formed on a substrate according to the present invention. In FIG. 2, numeral 1 denotes a substrate, numeral 2 denotes a first layer (cap layer), and numeral 3 denotes a second layer (the main film layer).

### BEST MODE FOR CARRYING OUT THE INVENTION

Hereafter, the present invention will be described in detail by the following embodiments.

(Silicon Oxynitride Protective Coat)

The protective coat according to the present invention is a protective coat formed on the top surface of a substrate, or on the top surface of a thin film layered body formed on the substrate. The protective coat is characterized by comprising silicon oxynitride in which the atomic ratio of Si/O/N is 100/X/Y (130≦X+Y≦180, 10≦X≦135, 5≦Y≦150).

According to the present invention, the above composition ratio of silicon oxynitride film is determined according to the ternary system of Si/O/N. This is based on the fact that when a Si component exerts the highest barrier property (moisture resistance) and the amount of a Si component is large compared to the N and O gas components, barrier properties are enhanced and visible light transmittance decreases, while in contrast, when the amount of a Si component is small compared to the N and O gas components, barrier properties are reduced and visible light transmittance increases.

The ratio of Si, a solid component, to the gaseous components O and N is, in terms of atomic weight ratio, more preferably 1:1.4 to 1:1.7, and in particular a ratio of approximately 2:3 is optimal. When this ratio is approximately 2:3, favorable barrier properties can be obtained while maintaining a transparency ratio of 80% or more.

Further, any ratio is suitable as the ratio of the N component to the O component as long as it falls within the above ratio ranges, and more preferably the N component and O component may have an atomic weight ratio between 2:3 and 4:1, and a ratio of approximately 1:1 is particularly preferable.

Experimentally, as described later, an atomic weight ratio for Si/N/0 of approximately 100/75/80 is optimal. In this case, favorable barrier properties of approximately WTR 0.01 can be obtained with a film thickness of 3000 A and wavelength transmittance at 550 nm of 83%.

According to the present invention, a substrate for forming a protective coat is not particularly limited as long as it can be applied to a vacuum process, and various kinds of substrate can be applied. In particular, a substrate that easily includes moisture or a substrate that is liable to generate emitted gas during the process of forming a protective coat is effective. As specific examples thereof, an organic layer in which it is difficult to cure an internal part of the film, such as a UV curable resin usable in organic electroluminescent devices and the like, or a film having a high moisture content such as acrylic UV curable resins, polyethylene naphthalate (PEN), polyethersulfone (PES) and the like used in packaging materials, display devices and so forth may be mentioned. When a protective coat (barrier layer) is formed on an organic layer as described above, the protective coat is commonly referred to as an “overcoat layer”.

A protective coat according to the present invention is not only a film formed directly on a substrate as described above, and may be a protective coat to cover a top part of a thin film layered body formed on a substrate. The actual configuration of the thin film layered body is not restricted in any manner, and it maybe any heretofore known configuration. For example, the protective coat is particularly useful with respect to a thin film layered body requiring moisture resistance or gas barrier properties, such as a thin film layered body that includes an organic luminescent layer. Further, in a case of directly forming a protective coat on a substrate, it is particularly useful when a configuration is one requiring moisture resistance or gas barrier properties, such as when a thin film layered body formed on a top part of the substrate is one that includes an organic luminescent layer. In addition, when a thin film layered body is, for example, a color filter layer, even in the case of laminating on top thereof another thin film layered body such as, for example, an organic EL device structure or a liquid crystal device structure, the protective coat according to the present invention can be formed on the former thin film layered body, such as a color filter layer, and/or on the latter thin film layered body.

In general, a structure having a color filter layer as a thin film layered body on a substrate such as glass or plastic is referred to as a “color filter substrate (CF substrate)”, and the protective coat according to the present invention is particularly useful when formed as a protective coat on this type of CF substrate. Herein, a CF substrate can include various forms, and examples thereof include a structure having a black matrix layer and a color filter layer laminated on a substrate, as well as a structure having a color conversion layer further laminated on a color filter layer.

The thickness of a protective coat according to the present invention is not particularly limited, and because the thickness will vary according to a substrate on which the protective coat is deposited or the type of a thin film layered body and the like it cannot be unconditionally stipulated. However, as described later, for a substrate having a large amount of emitted gas (specifically, for example, one having a hydrogen pressure of 1×10⁻⁵ Pa or higher when measured with a quadrupole mass spectrometer during film formation), if the film is of a thin thickness, for example 500 A or less, nitriding is difficult and there is the concern that a desired composition can not be formed. Therefore, a film thickness greater than this is preferable, and in particular, a film thickness of approximately 500 to 5000 A is preferable.

Next, a method for production of the protective coat according to the present invention will be described.

The method for production of the protective coat of the present invention is a method for producing a protective coat that is formed on a top part of a thin film layered body formed on a top part of a substrate or on a substrate and that is characterized by comprising silicon oxynitride in which the atomic ratio of Si/O/N is 100/X/Y (130≦X+Y≦180, 10≦X≦135, 5≦Y≦150), wherein the protective coat is formed by a sputtering method in which silicon nitride is used as a target material, an inert gas is used as a sputtering gas, and N₂ is used as a reactive feed gas. Alternatively, the protective coat is formed by an ion plating method using silicon nitride as a material and N₂ as a reactive feed gas, as described above.

More specifically, when forming a silicon oxynitride film on a top part of a thin film layered body formed on a top part of a substrate or on a substrate, the present inventors identified, from the results of analysis using a quadrupole gas analyzing apparatus, a phenomenon whereby oxygen derived from H₂O, the principal emitted gas component from a substrate, is preferentially incorporated into the film to inhibit nitriding and cause SiOx formation. The present inventors thus found a method of forming a desired SiOxNy film that inhibits SiOx formation of a protective coat with good reproducibility by using nitrogen gas rather than oxygen as a reactive gas to be introduced at a time of a film formation reaction.

With respect to this point, more specifically the present inventors attempted to produce a protective coat under the conditions disclosed in the above US2002093285A1 using mass-production type in-line equipment after designing a production process to be applied for practical use in industry. However, a SiOxNy film as described in US2002093285A1 could not be obtained as the result, and a SiOx-formed film was obtained instead. In view of this result, after concentrated studies the present inventors reached the conclusion that when employing the manufacturing conditions disclosed in JP2002-100469A, a SiOxNy film can only be formed when a relatively high output density is applied to a Si₃N₄ target, a distance between a substrate and a target is short, a batch type apparatus is used that is less subject to the influence of components of gas emitted from a substrate and, further, a substrate with a small amount of emitted gas components is used. We also concluded that with respect to a substrate having a large amount of emitted gas components, a SiOxNy film could not be stably manufactured using in-line type equipment (continuous system) applicable for mass production in which a distance between a substrate and a target is comparatively long. Therefore, from this observed result and the results of analysis using a quadrupole gas analyzing apparatus, the present inventors concluded that when forming a SiOxNy film by a sputtering method or ion plating method using in-line equipment applicable for mass production using a substrate with a large amount of emitted gas components, without supplying oxygen gas as a reactive gas in the reaction system as an oxygen source, oxygen generated by degradation of moisture that was present in a substrate or thin film layered body or in a reaction apparatus is incorporated into the film which is growing, and therefore the use of nitrogen gas and not oxygen as a reactive gas is desirable.

When forming a protective coat comprising silicon oxynitride of the above desired composition by a sputtering method, as described above silicon nitride (Si₃N₄) can be used as a target material. The density thereof is not particularly limited, and a density of approximately 50 to 80% is adequate.

In addition, a sputtering gas is not particularly limited as long as it is an inert gas, and Ar is commonly used.

N₂ can be used as a reactive feed gas, and since a compounding ratio of N₂ with respect to an inert gas will vary depending on the composition of a SiOxNy film to be obtained and the proportion of emitted gas from a substrate in the reaction system and the like, it can not be unconditionally stipulated. For example, the ratio of inert gas/N₂ may be a flow ratio of approximately 400 sccm/5 sccm to 400 sccm/20 sccm, and a ratio of about 400 sccm/10 sccm is particularly preferable. Where necessary, hydrogen pressure or the like in the reaction system during film formation may be detected using a quadrupole mass analyzing apparatus or the like, and the compounding ratio of N₂ may be suitably adjusted in accordance with the result.

Further, it is preferable that oxygen or an oxygen-containing gas such as air is substantially not included as a reactive feed gas. However a trace amount thereof of approximately 10⁻⁶ Pa or less (when measured with a quadrupole mass analyzing apparatus) is admissible.

A conventional in-line sputtering apparatus for mass production can be used in the method for producing a protective coat of the present invention. Herein, the term “in-line sputtering apparatus” means, as is common knowledge, an apparatus comprising a continuous system in which a plurality of items for processing are conveyed in succession into a reaction chamber, and having being conveyed into the reaction chamber, during a fixed period of time after being delivered from the reaction chamber each item for processing undergoes film formation treatment by sputtering. Any kind of in-line sputtering apparatus can be used as long as the apparatus is of the type described above. From the viewpoint of expediting nitriding of a protective coat, an apparatus having a high applied output and also having a short distance between a target and a substrate (TS interval distance) is preferable. For example, an apparatus having an applied output of approximately 6.5 W/cm² and a distance between a target and a substrate of approximately 8 cm is preferable.

Other conditions concerning sputtering are not particularly limited, and may be in accordance with known techniques.

When conducting film formation by an ion plating method the conditions are roughly the same as for a sputtering method, and a desired SiOxNy film can be formed utilizing an in-line ion plating apparatus for mass production, using the same materials and reactive feed gas as described above.

(Multilayered Protective Coat)

The protective coat of the present invention is a protective coat formed on the top part of a thin film layered body formed on a top part of a substrate or on a substrate. The protective coat is characterized by comprising two or more layers having at least a comparatively thin first layer formed on a top part of a thin film layered body formed on a top part of a substrate or on a substrate, and a comparatively thick second layer formed on a top part of the first layer and having a different composition to the first layer. FIG. 2 shows one example of the configuration thereof. In FIG. 2, a cap layer 2 that is a first layer is formed on a substrate 1, and the main film layer 3 that is a second layer is formed on top of the cap layer 2. The protective coat according to the present invention may be comprised of a plurality of layers that number greater than two. In FIG. 2, the film thickness of each layer is exaggerated for purposes of illustration.

As described above, according to the present invention a comparatively thin first layer (cap layer) is initially formed on the surface of a thin film layered body (hereafter, also called a “lower layer”) formed on a top part of a substrate or on a substrate to cover the surface of the lower layer, thereby blocking gas emitted from the lower layer at an early stage and inhibiting the influence of the emitted gas at a time of formation of a succeeding second layer (the main film layer). Therefore, even when forming the main film layer utilizing a substrate conveyor-type production apparatus using a target having a slow sputter rate while transporting a substrate at a slow conveying speed, there is no longer the concern about a deterioration in in-plane uniformity in the composition of the protective coat, which exists for a protective coat obtained through a conventional production method in which a cap layer as described above is not formed, and the formation of a protective coat of a desired composition and a desired thickness that has high in-plane uniformity is enabled.

The composition of a protective coat according to the present invention is not particularly limited, and it may be an inorganic film or an organic film. For example, an inorganic oxide, nitride or nitride-oxide such as AlN, Al₂O₃, SiOxNy, SiOx, SiNx or the like is preferable, and in particular, a composition providing SiOxNy as the composition of the overall protective coat is preferable from the point of view of barrier properties (moisture resistance) and the like. In this case, the first layer that is a cap layer may be a SiOx film and the second layer that is the main film layer may be SiOxNy or SiNx.

Herein, a composition of SiOxNy in which the atomic ratio of Si/O/N is 100/X/Y (130≦X+Y≦180, 10≦X≦135, 5≦Y≦150) is particularly preferable.

As described above, in the ternary system of Si/O/N, when a Si component exerts the highest barrier properties (moisture resistance) and the amount of a Si component is large compared to the N and O gas components, barrier properties are enhanced and visible light transmittance decreases, while in contrast, when the amount of a Si component is small compared to the N and O gas components, barrier properties are reduced and visible light transmittance increases.

The ratio of Si, a solid component, to the gaseous components O and N is, in terms of atomic weight ratio, more preferably 1:1.4 to 1:1.7, and in particular a ratio of approximately 2:3 is optimal. When this ratio is approximately 2:3, favorable barrier properties can be obtained while maintaining a transparency ratio of 80% or more.

Further, any ratio is suitable as the ratio of the N component to the O component as long as it falls within the above ratio ranges, and more preferably the N component and O component may have an atomic weight ratio between 2:3 and 4:1, and a ratio of approximately 1:1 is particularly preferable.

According to the present invention, a substrate for forming a protective coat is not particularly limited as long as it can be applied to a vacuum process, and various kinds of substrate can be applied. In particular, a substrate that easily includes moisture or a substrate that is liable to generate emitted gas during the process of forming a protective coat is effective. As specific examples thereof, an organic layer in which it is difficult to cure an internal part of the film, such as a UV curable resin usable in organic electroluminescent devices and the like, or a film having a high moisture content such as acrylic UV curable resins, polyethylene naphthalate (PEN), polyethersulfone (PES) and the like used in packaging materials, display devices and so forth may be mentioned. When a protective coat (barrier layer) is formed on an organic layer as described above, the protective coat is commonly referred to as an “overcoat layer”.

A protective coat according to the present invention is not only a film formed directly on a substrate as described above, and may be a protective coat to cover a top part of a thin film layered body formed on a substrate. The actual configuration of the thin film layered body is not restricted in any manner, and it may be any heretofore known configuration. For example, the protective coat is particularly useful with respect to a thin film layered body requiring moisture resistance or gas barrier properties, such as a thin film layered body that includes an organic luminescent layer. Further, in a case of directly forming a protective coat on a substrate, it is particularly useful when a configuration is one requiring moisture resistance or gas barrier properties, such as when a thin film layered body formed on a top part of the substrate is one that includes an organic luminescent layer. In addition, when a thin film layered body is, for example, a color filter layer, even in the case of laminating on top thereof another thin film layered body such as, for example, an organic EL device structure or a liquid crystal device structure, the protective coat according to the present invention can be formed on the former thin film layered body, such as a color filter layer, and/or on the latter thin film layered body.

In general, a structure having a color filter layer as a thin film layered body on a substrate such as glass or plastic is referred to as a “color filter substrate (CF substrate)”, and the protective coat according to the present invention is particularly useful when formed as a protective coat on this type of CF substrate. Herein, a CF substrate can include various forms, and examples thereof include a structure having a black matrix layer and a color filter layer laminated on a substrate, as well as a structure having a color conversion layer further laminated on a color filter layer.

The film thickness of a first layer (cap layer) of a protective coat according to the present invention is not particularly limited, and since the thickness will vary depending on a substrate on which the protective coat is deposited or the kind of thin film layered body as well as the type of material forming the cap layer and the method of manufacture and the like, it cannot be unconditionally stipulated. However, a first layer that does not grow in an island shape and forms a continuous layer uniformly covering a lower layer, and that has a thickness of 1500 A or less, preferably 700 A or less, is preferred. Preferably, a minimum thickness value is 200 A or more. Further preferably, a first layer (cap layer) will have a film thickness of approximately. 400 to 600 A.

Meanwhile, a second layer (the main film layer) is one required for exerting desired barrier properties and visible light transmittance, and since the thickness thereof will vary depending on a substrate on which the protective coat is deposited or the kind of thin film layered body as well as the type of material forming the cap layer and the method of manufacture and the like, it cannot be unconditionally stipulated. However, a layer having a thickness that is at least thicker than the first layer is desirable and, for example, a film thickness of 1500 to 3000 A, more preferably 2500 to 3000 A, is preferred.

Next, the method for producing the protective coat according to the present invention will be described.

A method for producing a protective coat of the present invention having a composition as described above is not particularly limited. However, production can be efficiently performed using a production method characterized in that a protective coat comprising two or more layers of different compositions is formed in a vacuum process using the same raw materials for film formation by controlling a conveying speed, wherein a first layer of film is produced while being allowed to react with components of gas emitted from a substrate or a thin film layered body formed on a substrate, and subsequently, at the time of formation of a second layer, the obtained first layer is applied as a cap layer to block gas emitted from a substrate or a thin film layered body formed on a substrate.

Specifically, when the principal emitted gas component from a lower layer is oxygen derived from H₂O, at the time of formation of a first layer, this oxygen is preferentially incorporated into the growing film. Therefore, in a vacuum process such as a sputtering or ion plating method using, for example, silicon nitride as a target material, at the time of formation of a first layer that receives significant influence from gas emitted from the lower layer, nitriding of the growing film is inhibited, and a SiOx-formed film is formed. Hence, the conveying speed of a substrate in the reaction system is quickened to form a thin first layer. After formation of a first layer, having temporarily exposed the substrate to atmosphere, film formation is then performed using the same target material, and since the first layer acts as a cap layer blocking gas emitted from the lower layer, nitriding proceeds in the growing film and an obtained second layer is of a different composition to the first layer, this is, SiOxNy or SiNx. While the above describes a case using silicon nitride as a target material, it is similarly possible to obtain film having a first and second layer of different compositions when using different raw materials for film formation.

With respect to the ratio of the conveying speed of a substrate at the time of film formation of a first layer to the conveying speed of a substrate at the time of film formation of a second layer, since the ratio will vary depending on the sputter rate of the material employed as a target and the desired film thickness to be obtained for the first layer and second layer and the like, the ratio cannot be unconditionally stipulated. For example, a ratio of from 15:2 to 2:1 can be employed as the ratio for (conveying speed at time of formation of a first layer): (conveying speed at time of formation of a second layer).

As described above, when attempting to obtain a protective coat comprising silicon oxynitride in which the atomic ratio of Si/O/N is 100/X/Y (130≦X+Y≦180, 10≦X≦135, 5≦Y≦150), which is one example of the composition of a preferred protective coat, preferably, the protective coat is formed by a sputtering method in which silicon nitride is used as a target material, an inert gas is used as a sputtering gas, and N₂ is used as a reactive feed gas, or is formed by an ion plating method using silicon nitride as a material and N₂ as a reactive feed gas.

This is based on the present inventors identifying from the results of analysis using a quadrupole gas analyzing apparatus when forming a silicon oxynitride film on a top part of a thin film layered body formed on a top part of a substrate or on a substrate, a phenomenon whereby oxygen derived from H₂O, the principal emitted gas component from a substrate, is preferentially incorporated into the film to inhibit nitriding and cause SiOx formation. The present inventors thus found a method of forming a desired SiOxNy film that inhibits SiOx formation of a protective coat with good reproducibility by using nitrogen gas rather than oxygen as a reactive gas to be introduced at the time of a film formation reaction. This point is described in more detail in the foregoing.

When forming a protective coat comprising silicon oxynitride by a sputtering method, as described above, silicon nitride (Si₃N₄) can be used as a target material. The density thereof is not particularly limited, and a density of approximately 50 to 80% is adequate.

In addition, a sputtering gas is not particularly limited as long as it is an inert gas, and Ar is commonly used.

N₂ can be used as a reactive feed gas, and since a compounding ratio of N₂ with respect to an inert gas will vary depending on the composition of a SiOxNy film to be obtained and the proportion of emitted gas from a substrate in the reaction system and the like, it can not be unconditionally stipulated. For example, the ratio of inert gas/N₂ may be a flow ratio of approximately 400 sccm/5 sccm to 400 sccm/20 sccm, and a ratio of about 400 sccm/10 sccm is particularly preferable. Where necessary, hydrogen pressure or the like in the reaction system during film formation may be detected using a quadrupole mass analyzing apparatus or the like, and the compounding ratio of N₂ may be suitably adjusted in accordance with the result.

Further, it is preferable that oxygen or an oxygen-containing gas such as air is substantially not included as a reactive feed gas. However a trace amount thereof of approximately 10⁻⁶ Pa or less (when measured with a quadrupole mass analyzing apparatus) is admissible.

A conventional in-line sputtering apparatus for mass production can be used in the method for producing a protective coat of the present invention. Herein, the term “in-line sputtering apparatus” means, as is common knowledge, an apparatus comprising a continuous system in which a plurality of items for processing are conveyed in succession into a reaction chamber, and having being conveyed into the reaction chamber, during a fixed period of time after being delivered from the reaction chamber each item for processing undergoes film formation treatment by sputtering. Any kind of in-line sputtering apparatus can be used as long as the apparatus is of the type described above. From the viewpoint of expediting nitriding of a protective coat, an apparatus having a high applied output and also having a short distance between a target and a substrate (TS interval distance) is preferable. For example, an apparatus having an applied output of approximately 6.5 W/cm² and a distance between a target and a substrate of approximately 8 cm is preferable.

Other conditions concerning sputtering are not particularly limited, and may be in accordance with known techniques.

When conducting film formation by an ion plating method the conditions are roughly the same as for a sputtering method, and a desired SiOxNy film can be formed utilizing an in-line ion plating apparatus for mass production, using the same materials and reactive feed gas as described above.

### EXAMPLES

Hereafter, the present invention will be explained in detail referring to examples.

### Example 1

### Method of Experiment

Polyethersulfone film (manufactured by Sumitomo Bakelite Co., Ltd., SUMILITE FST-5300) (hereunder, referred to as “PES”) was input into a sputtering vacuum chamber, evacuated to 10×10⁻⁵ Pa, and maintained in that state for 15 hours to form a barrier film.

Film formation conditions were as follows:
Target material: Si₃N₄ (manufactured by Toshima Seisakusho)
Ar/N2: 400 sccm/10 sccm (40:1)
Film formation pressure: 5 mTorr
Applied power: 4.3 kW
Film formation temperature: unheated (approximately 110° C.)
Film thickness: 3000 A Conveying speed: 58 mm/min
Overcoat layer: Nippon Steel Chemical Co., Ltd., ph5
Gas monitor during film formation: Quadrupole mass spectrometer (STADM-2000) manufactured by ULVAC Inc.
Three conveying carriers were used (first carrier: for ESCA (Si wafer/film); second carrier: measurement of film thickness, transmittance (glass); third carrier: (barrier measurement); all in the same batch)
   (Experiment Results)

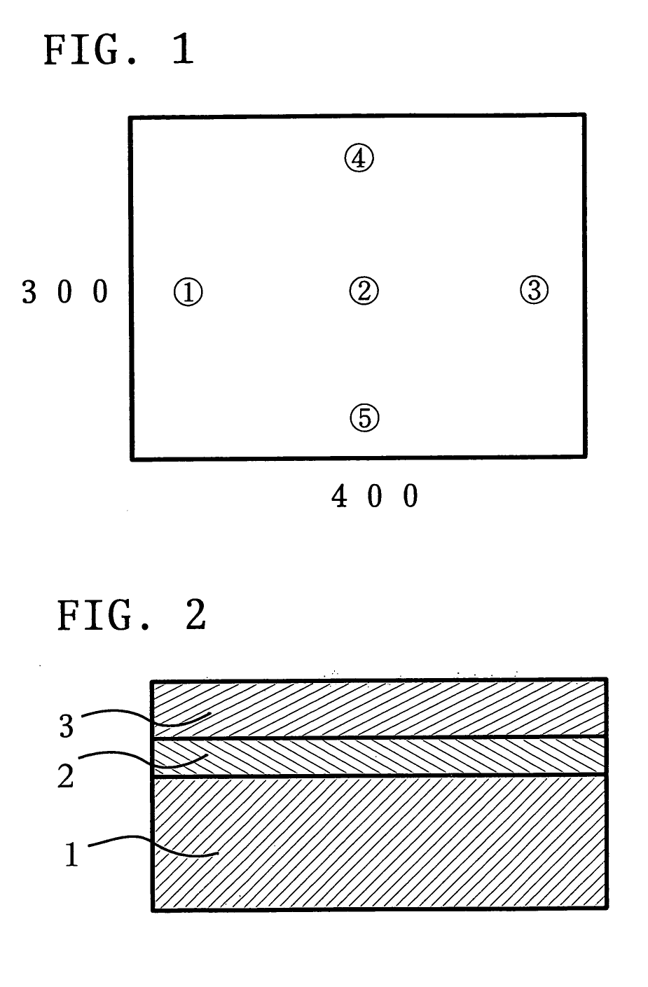

The results show in-plane composition distribution, transmittance distribution and in-plane barrier distribution of a substrate (PES film) that formed a barrier film (see FIG. 1 for evaluation points). Composition analysis was conducted using XPS (X-ray photoelectron spectroscopy apparatus, ESCA LAB 220i, manufactured by VG Systems).

Each measurement point is 2 cm from an edge of the substrate, and barrier measurement was conducted by a MOCON method using a 9 cm square area in the vicinity of the measurement points. In Table 1, “WTR” denotes water vapor barrier property and “OTR” denotes oxygen barrier property. Further, the conveying direction of a substrate is such that the side denoted by the numeral 3 in FIG. 1 is the leading edge and the side denoted by the numeral 1 is the trailing edge.

TABLE 1
(Measurement results: nitrogen only introduced, 3000 A)

| | | | | Barrier | Barrier |
|---|---|---|---|---|---|
| | Composition | Transmittance | Film | property | property |
| | (Si/O/N) | (%) | thickness | (WTR) | (OTR) |
| 1 | 100/74/80 | 80 | 3000 A | 0.035 | 0.18 |
| 2 | 100/82/71 | 85 | 3000 A | 0.041 | 0.21 |
| 3 | 100/99/64 | 92 | 3000 A | 0.075 | 0.24 |
| 4 | 100/83/72 | 87 | 2900 A | 0.032 | 0.22 |
| 5 | 100/84/71 | 86 | 2900 A | 0.032 | 0.21 |

Composition analysis was conducted using ESCA. A Si wafer was provided at points 1 to 5 on a film substrate to perform composition analysis. In the measurement, separate carriers were formed in the same batch for measurement of film thickness, barrier properties, and transmittance.

Further, a value for a depth of approximately 100 A and a value on the top surface were measured. There was no significant difference in the values, and the above values represent the values for the top surface.

Also, a separate carrier was similarly used to measure film thickness, in which a film formed on glass was peeled off by a lift-off method and evaluated.

### Referencial Example 1

Film formation was conducted in the same manner as in Example 1, with the exception of employing a film thickness of 500 A, and a conveying speed of 290 mm/min.

PES film was used as a substrate, and in the same manner as shown in FIG. 1, evaluation of in-plane composition distribution, transmittance distribution and in-plane barrier distribution was conducted. The results are shown below.

TABLE 2
(Measurement results: nitrogen only introduced, 500 A)

| | | | | Barrier | Barrier |
|---|---|---|---|---|---|
| | Composition | Transmittance | Film | property | property |
| | (Si/O/N) | (%) | thickness | (WTR) | (OTR) |
| 1 | 100/170/2 | 97 | 500 A | 0.55 | 0.3 |
| 2 | 100/172/— | 98 | 500 A | 0.61 | 0.4 |
| 3 | 100/175/— | 99 | 500 A | 0.75 | 0.55 |
| 4 | 100/173/— | 98 | 500 A | 0.62 | 0.35 |
| 5 | 100/174/— | 99 | 500 A | 0.62 | 0.37 |

A favorable value was not achieved for barrier properties, and in-plane inconsistencies existed.

Further, regardless of the introduction of only Ar and nitrogen gas, the results were the same in that the composition was mostly SiO₂ and nitriding did not occur.

### Comparative Example 1

Next, film formation was performed under conditions close to conditions E described in Table 2 of US2002093285A1. Film formation was conducted by adjusting the Ar ratio and (O₂, N₂) ratio to secure visible light transmittance.
N/O=8.5 (Ar/N/O:380/8.5/1)

TABLE 3
(Measurement results: nitrogen and oxygen (mainly nitrogen)
introduced, 3000 A)

| | | | | Barrier | Barrier |
|---|---|---|---|---|---|
| | Composition | Transmittance | Film | property | property |
| | (Si/O/N) | (%) | thickness | (WTR) | (OTR) |
| 1 | 100/180/5 | 82 | 3000 A | 0.74 | 0.32 |
| 2 | 100/182/2 | 85 | 3000 A | 0.81 | 0.39 |
| 3 | 100/186/— | 91 | 3000 A | 0.92 | 0.58 |
| 4 | 100/183/2 | 87 | 3000 A | 0.81 | 0.37 |
| 5 | 100/184/— | 85 | 3000 A | 0.82 | 0.38 |

Nitriding was observed to a certain extant, but the obtained film was virtually a SiOx film.

### Comparative Example 2

Next, film formation was performed under conditions close to conditions K described in Table 2 of US2002093285A1. Film formation was conducted by adjusting the Ar ratio and (O₂, N₂) ratio to secure visible light transmittance.
N/O=0.05 (Ar/N/0:400/0.5/9.5)

TABLE 4
(Measurement results: nitrogen and oxygen (mainly oxygen)
introduced, 3000 A)

| | | | | Barrier | Barrier |
|---|---|---|---|---|---|
| | Composition | Transmittance | Film | property | property |
| | (Si/O/N) | (%) | thickness | (WTR) | (OTR) |
| 1 | 100/180/— | 83 | 3000 A | 0.72 | 0.31 |
| 2 | 100/182/— | 86 | 3000 A | 0.85 | 0.38 |
| 3 | 100/186/— | 95 | 3000 A | 0.96 | 0.6 |
| 4 | 100/183/— | 87 | 3000 A | 0.85 | 0.38 |
| 5 | 100/184/— | 84 | 3000 A | 0.83 | 0.39 |

Nitriding was not observed, and the resulting film was a SiOx film.

It is considered that the reason nitriding was not substantially observed in Comparative Examples 1 and 2 is that in an in-line type film formation apparatus used for mass production the TS interval distance (distance between a target and a substrate) is comparatively long, and therefore nitrogen discharged from the target collided with oxygen, which has high reactivity, before arriving at the substrate. Thus the nitrogen was deprived of its activity and oxygen was preferentially incorporated into the film.

The results can be improved to a certain extent by lowering the film formation pressure (for example, to 2 mTorr or less) and lengthening the mean free path, however this is not preferable since film stress will increase to render the film liable to cracking. Further, making the film formation pressure a low pressure is also not preferable with respect to discharge stability.

### Referencial Example 3

In order to incorporate a nitrogen component included in the target material into a film under the conditions described in Control 1 (nitrogen/oxygen=8.5), film formation was conducted by raising the RF power (4.5 kW) and increasing the Ar flow ratio (Ar/N/O:400/8.5/1) so that a transmittance of 85% could be maintained.

TABLE 5
(Measurement results: nitrogen and oxygen (mainly nitrogen)
introduced, 3000 A)

| | | | | Barrier | Barrier |
|---|---|---|---|---|---|
| | Composition | Transmittance | Film | property | property |
| | (Si/O/N) | (%) | thickness | (WTR) | (OTR) |
| 1 | 100/180/10 | 83 | 3000 A | 0.69 | 0.22 |
| 2 | 100/182/8 | 85 | 3000 A | 0.75 | 0.25 |
| 3 | 100/186/2 | 89 | 3000 A | 0.81 | 0.37 |
| 4 | 100/183/4 | 87 | 3000 A | 0.73 | 0.27 |
| 5 | 100/184/— | 83 | 3000 A | 0.74 | 0.28 |

As shown in Table 5, although nitriding was observed, it was of an insufficient amount.

### Example 2

### Method of Experiment

Polyethersulfone film (manufactured by Sumitomo Bakelite Co., Ltd.; product name: SUMILITE FST-5300) (hereunder, referred to as “PES”) was input into a sputtering vacuum chamber, evacuated to 1×10-5 Pa, and maintained in that state for 15 hours to form a barrier film.

Film formation conditions were as follows:
Target material: Si₃N₄ (manufactured by TOSHIMA MFG CO., LTD.)
Ar/N2: 400 sccm/10 sccm (40:1)
Film formation pressure: 5 mTorr
Applied power: 4.3 kW
Film formation temperature: unheated (approximately 110° C.)
Film thickness: First layer (cap layer): 500 A
Conveying speed: 290 mm/min
Second layer (the main film layer): 2500 A
Conveying speed: 58 mm/min
Total film thickness: 3000 A
Overcoat layer: Nippon Steel Chemical Co., Ltd., ph5
Gas monitor during film formation: Quadrupole mass spectrometer (STADM-2000) manufactured by ULVAC Inc.
Three conveying carriers were used (first carrier: for ESCA (Si wafer/film); second carrier: measurement of film thickness, transmittance (glass); third carrier: (barrier measurement); all in the same batch)
Film formation: film formation was conducted twice (after formation of a first layer, the layer was exposed to atmosphere and then formation of a second layer was conducted).
   (Experiment Results)

Film formation of a cap layer was performed using PES film, and similarly to the case of above Example 1, evaluation of in-plane composition distribution, transmittance distribution and in-plane barrier distribution was conducted at the points shown in FIG. 1. The results are shown in Tables 6 and 7. Evaluation was conducted at two separate times: once after formation of a cap layer, and once after formation of the main film layer.

TABLE 6
(Measurement results: cap layer/substrate)

| | | | | Barrier | Barrier |
|---|---|---|---|---|---|
| | Composition | Transmittance | Film | property | property |
| | (Si/O/N) | (%) | thickness | (WTR) | (OTR) |
| 1 | 100/170/2 | 97 | 500 A | 0.55 | 0.3 |
| 2 | 100/172/— | 98 | 500 A | 0.61 | 0.4 |
| 3 | 100/175/— | 99 | 500 A | 0.75 | 0.55 |
| 4 | 100/173/— | 98 | 500 A | 0.62 | 0.35 |
| 5 | 100/174/— | 99 | 500 A | 0.62 | 0.37 |

A favorable value was not achieved for barrier properties, and in-plane inconsistencies existed.

Further, the results were the same in that the composition was mostly SiO₂ and nitriding did not occur.

TABLE 7
(Measurement results: the main film layer/cap layer/substrate)

| | | | | Barrier | Barrier |
|---|---|---|---|---|---|
| | Composition | Transmittance | Film | property | property |
| | (Si/O/N) | (%) | thickness | (WTR) | (OTR) |
| 1 | 100/71/80 | 86 | 3000 A | 0.017 | 0.11 |
| 2 | 100/70/81 | 85 | 3000 A | 0.016 | 0.10 |
| 3 | 100/70/80 | 85 | 3000 A | 0.015 | 0.11 |
| 4 | 100/70/81 | 86 | 2900 A | 0.015 | 0.11 |
| 5 | 100/71/81 | 86 | 2900 A | 0.016 | 0.11 |

Composition analysis was performed in the same manner as for the first film formation layer using ESCA. Composition analysis was performed by providing a Si wafer at positions 1 to 5 on a film substrate. The results showed that inconsistencies in composition and inconsistencies in transmittance did not occur.

Further, barrier properties were improved in comparison to the results for a film produced without providing a cap layer, i.e. the results in Example 1 above (see Table 1). Therefore, regardless of the fact of using the same target material, introduced gas and film formation pressure, by means of only a difference in conveying speed a SiOx film was formed as the first layer and a SiONx film was formed as the second layer.

### Example 3

A UV-curable type overcoat material (UV-curable resin, ph-5, manufactured by Nippon Steel Chemical Co., Ltd.) was spin-coated and cured on a glass substrate at a thickness of 5 μm, then the coated substrate was input into a sputtering vacuum chamber as a evaluation substrate, evacuated to 1×10⁻⁵ Pa, to form a barrier film under the same film formation conditions as in the above Example 2.

Further, on top thereof, film formation was conducted for Cr: 1000 A and ITO: 1500 A under the following conditions, and patterning was evaluated.

(Cr Film Formation Conditions)

Target material: Cr
Ar: 100 sccm
   Film formation pressure: 5 mTorr
   Applied power: 1.5 kW
   Film formation temperature: unheated
      (ITO Film Formation Conditions)
Target material: ITO
Ar/O₂: 100 sccm/2.5 sccm
   Film formation pressure: 5 mTorr
   Applied power: 2.5 kW
   Film formation temperature: unheated
ITO etchant: hydrochloric acid etchant; hydrochloric acid nitric acid: water (1:0.08:1)
Cr etchant: ceric ammonium nitrate etchant (IT-ELM, manufactured by The Intec Co., Ltd.)
Resist: S-1805, manufactured by Shipley Company, Inc.
   (Evaluation Result)

In the control, i.e. a sample where film formation of a cap layer was not conducted, ITO and Cr electrodes and the like were formed on a SiON/glass substrate and evaluation was conducted for a 10 μm-line pattern on the base. However, possibly because the composition of a lower layer was different, some inconsistencies arose in the etching rate and homogeneous patterning over the entire surface of a 300×400 substrate was difficult.

In contrast, in a sample according to the present invention having a cap layer formed thereon, when ITO and Cr electrodes and the like were formed on a SiON/glass substrate and evaluation was conducted for a 10 μm-line pattern on the base, etching inconsistencies did not tend to arise and patterning was performed without difficulty.

### Example 4

### Formation of Display Layer

A color filter layer was formed as a display layer on a glass substrate as follows.

First, a thin chromic oxide film was formed on a substrate by sputtering. A photoresist was applied onto the thin chromic oxide film, and mask exposure, development, and etching of the thin chromic oxide film were carried out sequentially to form a black matrix distributed in a matrix shape.

Next, photosensitive coating compositions for forming color filter layers for each of the colors red, green, and blue were prepared and applied on a substrate on which the above black matrix was formed. After drying, exposure and development were performed using a photomask, thereby forming color filter layers on which the pattern of each of the three colors were disposed.

A transparent photosensitive resin composition that dispersed a blue-emitting phosphor was applied on the color filter layer formed as above on the black matrix, and patterning was performed by a photolithography method to form a layer on the above blue color filter layer.

Next, according to the same procedure as described above, a green-converting phosphor layer was formed on the above green color filter layer, and a red-converting phosphor layer was formed on the above red color filter layer, to thereby form a conversion layer of each color.

(Formation of First Layer (Cap Layer))

Next, on the above conversion layers, a protective coat was formed over the entire surface by a sputtering method under the following conditions.
Target material: Si₃N₄
Ar/N₂: 400 sccm/10 sccm (40:1)
Film formation pressure: 5 mTorr
Applied power: 4.3 kW
Film formation temperature: unheated (approximately 110° C.)
Film thickness: 500 A

(Formation of Second Layer (the Main Film Layer))

On the above first layer, a silicon oxides-nitride (SiON) film was formed over the entire surface under the same conditions as for formation of the first layer, thereby forming a second layer.

(Production of a Visual Display Apparatus)

After formation of an electrode layer, insulating layer and cathode separator on a CF substrate having the above protection film, an organic EL luminescent layer was formed, and counter electrodes were formed on the organic EL luminescent layer to produce a visual display apparatus.

The resulting sample displayed favorable display characteristics in respect of both barrier properties and electrode patterning properties (when driven by PM, the luminance level of 150 cd/m² was maintained for 10000 h or more, generation of dark spots was not observed, and display defects caused by electrode etching inconsistencies were also not observed).

The same test was conducted using, in place of the above CF substrate having a color conversion layer on a top part of a color filter layer, a CF substrate not having this type of color conversion layer on a top part of a color filter layer, and roughly the same result was obtained.

### Comparative Example 3

A visual display apparatus was produced by forming an electrode layer, insulating layer, cathode separator, organic EL luminescent layer and counter electrodes on a CF substrate in the same manner as in the above Example 4, with the exception that a protective coat comprising a first layer and second layer was not formed.

The properties of the obtained sample were evaluated in the same manner as in Example 4. It was found that when driven by PM at a high temperature of 85° C., the luminance level of 150 cd/m² reduced by half at about 1 h, pixel reduction occurred, and display defects caused by electrode etching inconsistencies were also observed.

The same test was conducted using, in place of the above CF substrate having a color conversion layer on a top part of a color filter layer, a CF substrate not having this type of color conversion layer on a top part of a color filter layer, and roughly the same result was obtained.

### Referencial Example 4

A protective coat comprising a single layer of a thickness of 3000 A was formed under the conditions for forming the second layer according to the above Example 4, with the exception that a first layer was not formed. Thereafter, under the same conditions as in Example 4, an electrode layer, insulating layer, cathode separator, organic EL luminescent layer and counter electrodes were formed on a CF substrate to produce a visual display apparatus.

The properties of the obtained sample were evaluated in the same manner as in Example 4. It was found that when driven by PM at a high temperature of 85° C., the luminance level of 150 cd/m² reduced by half at about 1,000 h, the sample displayed superior properties to those of the sample of Comparative Example 3.

The same test was conducted using, in place of the above CF substrate having a color conversion layer on a top part of a color filter layer, a CF substrate not having this type of color conversion layer on a top part of a color filter layer, and roughly the same result was obtained.

1. A protective coat formed on the top surface of a substrate, or on the top surface of a thin film layered body formed on the substrate, comprising silicon oxynitride in which the atomic ratio of Si/O/N is 100/X/Y (130≦X+Y≦180, 10≦X≦135, 5≦y≦150).

2. The protective coat according to claim 1, wherein a thin film layered body that includes an organic luminescent layer is further formed on the top surface of the protective coat.

3. The protective coat according to claim 1, wherein the protective coat is formed on a substrate having a color filter layer formed thereon.

4. A method for producing a protective coat formed on the top surface of a substrate, or on the top surface of a thin film layered body formed on the substrate and comprising silicon oxynitride in which the atomic ratio of Si/O/N is 100/X/Y (130≦X+Y≦180, 10≦X≦135, 5≦Y≦≦150), wherein the protective coat is formed by a sputtering method in which silicon nitride is used as a target material, an inert gas is used as a sputtering gas, and N₂ is used as a reactive feed gas.

5. A method for producing a protective coat formed on the top surface of a substrate, or on the top surface of a thin film layered body formed on the substrate and comprising silicon oxynitride in which the atomic ratio of Si/O/N is 100/X/Y (130≦X+Y≦180, 10≦X≦135, 5≦Y≦150), wherein the protective coat is formed by an ion plating method in which silicon nitride is used as a material and N₂ is used as a reactive feed gas.

6. The method for producing a protective coat according to claim 4, characterized in that the oxygen component of the obtained protective coat comprising the silicon oxynitride is incorporated into the composition of the protective coat by degradation of moisture that was present in the substrate or the thin film layered body or in the reaction apparatus.

7. The method for producing a protective coat according to claim 4, wherein the protective coat comprising the silicon oxynitride is produced using an in-line sputtering apparatus, employing conditions of an applied output of 2.50 to 7.00 W/cm² and a distance between the target and the substrate of 12 cm or less.

8. The method for producing a protective coat according to claim 6, wherein the protective coat comprising the silicon oxynitride is produced using an in-line sputtering apparatus, employing conditions of an applied output of 2.50 to 7.00 W/cm² and a distance between the target and the substrate of 12 cm or less.

9. The method for producing a protective coat according to claim 5, characterized in that the oxygen component of the obtained protective coat comprising the silicon oxynitride is incorporated into the composition of the protective coat by degradation of moisture that was present in the substrate or the thin film layered body or in the reaction apparatus.

10. A protective coat formed on the top surface of a substrate, or on the top surface of a thin film layered body formed on the substrate, comprising two or more layers having at least a comparatively thin first layer formed on the top surface of a substrate, or on the top surface of a thin film layered body formed on the substrate, and a comparatively thick second layer formed on the top surface of the first layer and having a different composition from the first layer.

11. The protective coat according to claim 10, wherein the first layer is an oxide film and the second layer is a nitride oxide film or a nitride film.

12. The protective coat according to claim 10, wherein the first layer is a SiOx film and the second layer is SiONx or SiNx.

13. The protective coat according to claim 12, wherein the second layer is silicon oxynitride in which the atomic ratio of Si/O/N is 100/X/Y (130≦X+Y≦180, 1≦X≦135, 5≦Y≦150).

14. The protective coat according to claim 10, characterized in that the first layer does not grow in an island shape, but forms a continuous layer uniformly covering the lower layer, and has thickness of 1500 A or less.

15. The protective coat according to claim 10, wherein a thin film layered body including an organic luminescent layer is further formed on the top surface of the protective coat.

16. The protective coat according to claim 10, wherein the protective coat is formed on a substrate having a color filter layer formed thereon.

17. A method for producing the protective coat according to claim 10, characterized in that a protective coat comprising two or more layers of different compositions is formed in a vacuum process using the same raw materials for film formation by controlling a conveying speed, wherein the first layer is produced while being allowed to react with a component of gas emitted from the substrate or the thin film layered body formed on the substrate, and subsequently, at the time of formation of the second layer, the obtained first layer acts as a cap layer to block the gas emitted from the substrate or the thin film layered body formed on the substrate.

18. The method for producing a protective coat according to claim 16, characterized in that the first layer is an oxide film and the second layer is a nitride oxide film or a nitride film, wherein the oxygen component of the obtained protective coat is incorporated into the composition of the protective coat by degradation of moisture that was present in the substrate or the thin film layered body or in the reaction apparatus.
